(19) United States
(12) Patent Application Publication
(10) Pub. No.: US 2006/0186531 A1
(43) Pub. Date: Aug. 24, 2006

(54) Package structure with chip embedded in substrate

(75) Inventor: Shih-Ping Hsu, Hsin-Chu (TW)

Correspondence Address: EDWARDS & ANGELL, LLP, P.O. BOX 55874, BOSTON, MA, 02205, US

(73) Assignee: Phoenix Precision Technology Corporation, Hsin-Chu (TW)

(21) Appl. No.: 11/267,708

(22) Filed: Nov. 3, 2005

(30) Foreign Application Priority Data
Feb. 22, 2005 (TW) 094105183

(51) Int. Cl. H01L 23/12

(52) U.S. Cl. 257/700

(57) ABSTRACT

A package structure with chip embedded in substrate includes: a carrier having a stepped cavity; a semiconductor chip (or a chip set) received in the cavity of the carrier; a dielectric layer formed on the semiconductor chip and the carrier and filled in a gap between the semiconductor chip and the cavity of the carrier to fix the semiconductor chip in the carrier; and a circuit layer formed on the dielectric layer, and electrically connected to electrode pads of the semiconductor chip via a plurality of conductive structures so as to provide external electrical extension for the semiconductor chip via the circuit layer.

### FIELD OF THE INVENTION

The present invention relates to package structures with chips embedded in substrates, and more particularly, to a package structure integrated with a semiconductor chip.

### BACKGROUND OF THE INVENTION

There have been developed various package types of semiconductor devices along with evolution of the semiconductor packaging technology. Basically in a semiconductor package structure, a semiconductor chip is mounted on and electrically connected to a package substrate or lead frame, and then an encapsulant is formed for encapsulating the semiconductor chip. Ball Grid Array (BGA) package employs one of advanced semiconductor packaging technologies, which is characterized in that a package substrate is utilized for mounting a semiconductor chip on a front surface thereof, and a plurality of array-arranged solder balls are implanted on a back surface of the package substrate by using a self-alignment technique, thereby allowing more I/O connections (e.g. solder balls) to be accommodated on a chip carrier (e.g. the package substrate) within the same unit area so as to satisfy the high-integration requirement of the semiconductor chip, such that the entire package unit can be bonded and electrically connected to an external device.

In a conventional semiconductor package structure, a semiconductor chip is mounted on a front surface of a substrate and is electrically connected to the substrate by a wire-bonding or flip-chip technique, and then the semiconductor chip is encapsulated; and solder balls are implanted on a back surface of the substrate for external electrical connection. Although such arrangement achieves incorporation of a large number of I/O connections in the semiconductor package structure, the electrical performances thereof are limited and hardly improved due to a long electrical connection path of wires during high-frequency or high-speed operation. Moreover, since a plurality of connection interfaces are required for the conventional packaging processes, the fabrication costs are accordingly increased.

Therefore, in order to effectively improve the electrical quality of package structure for use in products of next generation, it has endeavored to embed a chip in a carrier to provide direct electrical connection, shorten an electrical connection path, reduce signal loss and signal distortion, and improve performances in high-speed operation.

FIG. 1 shows a semiconductor package disclosed by U.S. Pat. No. 6,709,898. As shown in FIG. 1, the semiconductor package comprises: a heat spreader 102 having at least one recess 104; a semiconductor chip 114 mounted via a non-active surface thereof in the recess 104 by a thermally conductive adhesive 118; and a circuit built-up structure 122 formed by a built-up technique on the heat spreader 102 and the semiconductor chip 114. The recess 104 of the heat spreader 102 extends from an upper surface of the heat spreader 102 to the interior of the heat spreader 102 by a predetermined depth, and the semiconductor chip 114 is attached to a bottom surface of the recess 104 by the thermally conductive adhesive 118. A conventional hot pressing process is performed on the semiconductor chip 114 and the heat spreader 102 to allow a dielectric material to flow into the recess 104 and fill a space between the semiconductor chip 114 and the heat spreader 102.

However, when the dielectric material flows into the recess 104, the space in the recess 104 cannot be completely filled with the dielectric material due to restriction of size of the recess 104 and surface tension of the dielectric material itself, thereby easy to cause gaps or voids. During a subsequent thermal cycle for the semiconductor package, air within the gaps or voids may expand by heat to press the chip in the semiconductor package or even explode to damage the chip. Moreover, since the dielectric material cannot fill the recess 104 completely, this results in poor surface planarity of the dielectric material, making the semiconductor package not able to be applied to high-level integrated circuit products.

Furthermore, although circuits can be directly extended from the chip in the foregoing semiconductor package to shorten the electrical connection path and improve the performance in high-speed operation, such semiconductor package is normally embedded with only one semiconductor chip and not able to provide a multi-functional module structure, such that the conventional packaging technology does not satisfy the development tendency of electronic products with the requirement of multi-functionality nowadays.

### SUMMARY OF THE INVENTION

In light of the foregoing drawbacks in the conventional technology, an objective of the present invention is to provide a package structure with chip embedded in substrate, which can effectively position a semiconductor chip in a chip carrier.

Another objective of the present invention is to provide a package structure with chip embedded in substrate, in which a plurality of semiconductor chips can be integrated to thereby improve the electrical performances of an electronic product incorporating the package structure.

Still another objective of the present invention is to provide a package structure with chip embedded in substrate, in which planarity and consistency of semiconductor elements embedded in a cavity of a carrier can be maintained to thereby improve capability of performing subsequent fine-circuit fabrication processes.

A further objective of the present invention is to provide a package structure with chip embedded in substrate, for integrating fabrication processes of semiconductor chip and substrate, so as to provide greater flexibility to satisfy clients' requirements, reduce the fabrication costs and processes, and simplify an interface integration problem for the package structure.

In accordance with the above and other objectives, the present invention proposes a package structure with chip embedded in substrate, comprising: a carrier having at least one stepped cavity; at least one semiconductor chip received in the cavity of the carrier; and a dielectric layer formed on the semiconductor chip and the carrier and filled in a gap between the semiconductor chip and the cavity of the carrier so as to fix the semiconductor chip in the carrier. The package structure further comprises at least one circuit layer formed on the dielectric layer and electrically connected to the semiconductor chip.

In one embodiment of the present invention, the carrier can be an integrally formed structure, and openings with different sizes are sequentially formed in the carrier to form the stepped cavity. Alternatively, the carrier with the stepped cavity may be formed by stacking a plurality of carrier layers having openings with different sizes and corresponding locations to each other.

Thus, in the package structure with chip embedded in substrate according to the present invention, the stepped cavity is provided in the carrier and has an increased opening size step by step from bottom to top, such that a material of the dielectric layer can be easily filled into the gap between the semiconductor chip and the cavity of the carrier to effectively fix the semiconductor chip in the carrier. This maintains surface planarity and consistency of the dielectric layer of the carrier with the semiconductor chip received therein, and further improves the reliability of subsequent processes for fabricating circuits on the dielectric layer.

Moreover, the present invention proposes another package structure with chip embedded in substrate, which is substantially the same as the foregoing package structure but differs in that a chip set comprising a plurality of semiconductor chips is received in the stepped cavity of the carrier. These semiconductor chips are adjacently mounted on step surfaces of the stepped cavity, such that by subsequently forming a dielectric layer and a circuit layer on the semiconductor chips and the carrier, the semiconductor chips can be electrically interconnected via the circuit layer so as to shorten an electrical connection path between the semiconductor chips received in the cavity of the carrier, and improve transmission quality of electrical signals between the semiconductor chips, as well as reduce distortion of received signals, thereby achieving the purpose of high-speed transmission of signals. This therefore forms a multi-chip module structure satisfying the requirement of multi-functionality for electronic products nowadays.

In addition, since the package structure in the present invention can integrate the fabrication and packaging processes of semiconductor element and carrier, thereby providing greater flexibility to satisfy clients' requirements and simplifying fabrication processes and an interface coordination problem for semiconductor manufacturers.

### BRIEF DESCRIPTION OF THE DRAWINGS

The present invention can be more fully understood by reading the following detailed description of the preferred embodiments, with reference made to the accompanying drawings, wherein:

FIG. 1A (PRIOR ART) is a cross-sectional view showing a semiconductor package disclosed by U.S. Pat. No. 6,709,898;

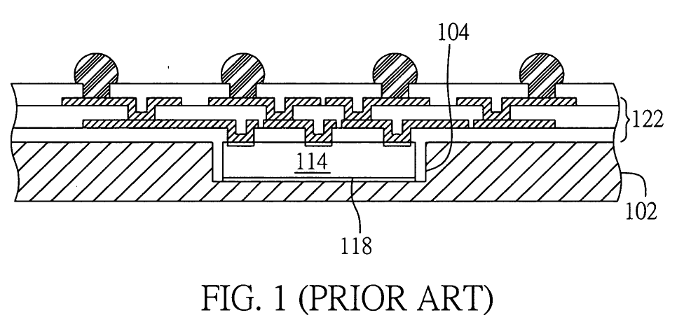

FIGS. 2A and 2B are cross-sectional views showing a package structure with chip embedded in substrate according to a first preferred embodiment of the present invention; and

FIGS. 3A and 3B are cross-sectional views showing a package structure with chip embedded in substrate according to a second preferred embodiment of the present invention.

### DETAILED DESCRIPTION OF THE PREFERRED EMBODIMENTS

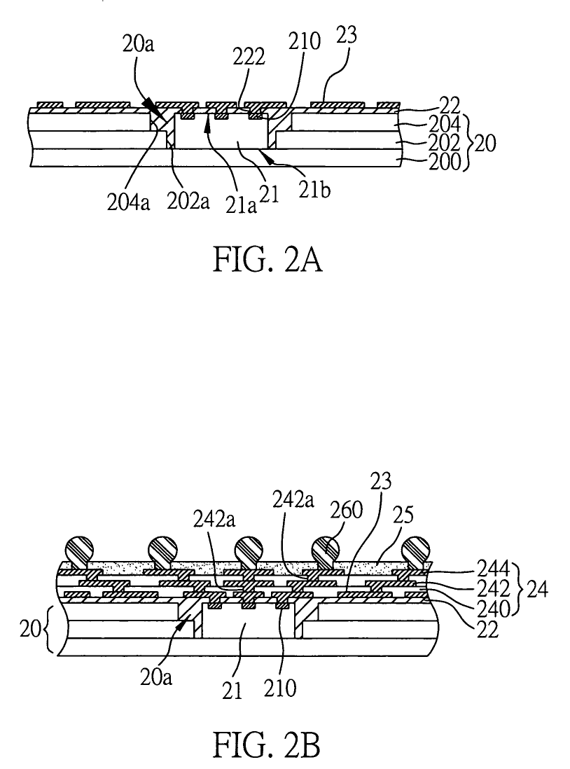

FIG. 2A shows a cross-sectional view of a package structure with chip embedded in substrate according to a first preferred embodiment of the present invention. As shown in FIG. 2A, the package structure comprises a carrier 20 having at least one stepped cavity 20a; at least one semiconductor chip 21 received in the stepped cavity 20a of the carrier 20; and a dielectric layer 22 formed on the semiconductor chip 21 and the carrier 20 and filled in a gap between the semiconductor chip 21 and the cavity 20a of the carrier 20 to fix the semiconductor chip 21 in the carrier 20. The package structure may further comprises a circuit layer 23 formed on the dielectric layer 22 and electrically connected to the semiconductor chip 21.

In this embodiment of the present invention, the carrier 20 is formed by stacking a plurality of carrier layers, wherein the carrier layers except the bottommost one are each provided with at least one through opening, and the openings are increased in size layer by layer from bottom to top. An example of a three-layered carrier structure is illustrated here in this embodiment. The carrier 20 comprises a first carrier layer 200, a second carrier layer 202 and a third carrier layer 204. The second carrier layer is mounted on the first carrier layer 200 and has at least one through opening 202a, wherein one side of the opening 202a is sealed by the first carrier layer 200. The third carrier layer 204 is formed with at least one through opening 204a at a position corresponding to the opening 202a of the second carrier layer 202, wherein the size of the opening 204a is larger than that of the opening 202a to thereby form the stepped cavity 20a with increased opening size step by step from bottom to top in the carrier 20. The first, second and third carrier layers may be an arbitrary combination of an insulating layer, a metallic layer, a ceramic layer, and a substrate formed with an internal circuit layer. It should be noted that, the above three-layered carrier structure only provides an example of the carrier 20 but not for limiting the present invention, and the number of layers of the carrier 20 may be any number according to practical requirements, for example, four layers, five layers or even more layers.

Alternatively, the carrier 20 may be an integrally formed structure, wherein the stepped cavity 20a with increased opening size step by step from bottom to top is obtained by sequentially forming openings with different sizes in the carrier 20.

The semiconductor chip 21 has an active surface 21a and a non-active surface 21b opposed to the active surface 21a. The non-active surface 21b of the semiconductor chip 21 is mounted on the first carrier layer 200 to receive the semiconductor chip 21 in the stepped cavity 20a. A plurality of electrode pads 210 are provided on the active surface 21a of the semiconductor chip 21. The semiconductor chip 21 may be an active chip or a passive chip, for example, capacitor silicon chip, memory chip, Application Specific Integrated Circuit (ASIC) chip, or CPU chip, etc.

The dielectric layer 22 may be made of a material, for example, epoxy resin, polyimide, cyanate ester, glass fiber, bismaleimide triazine (BT), or a mixture of epoxy resin and glass fiber, etc.

The circuit layer 23 is formed on the dielectric layer 22, and is electrically connected to the electrode pads 210 of the semiconductor chip 21 by conductive structures 222 (e.g. conductive blind holes or bumps) formed in the dielectric layer 22. Since a fabrication method of the circuit layer 23 utilizes conventional technology well known in the art, it is not to be further described herein.

Therefore, in the package structure with chip embedded in substrate according to the present invention, the semiconductor chip 21 is accommodated in the stepped cavity 20a of the carrier 20, and the stepped cavity 20a has an increased opening size step by step from bottom to top to facilitate filling of a material of the dielectric layer 22 in the gap between the semiconductor chip 21 and the cavity 20a of the carrier 20, such that the semiconductor chip 21 is effectively fixed in the carrier 20, and the quality and reliability of the package structure are both improved.

Subsequently for the package structure in the present invention, a circuit building-up process may be performed on the dielectric layer 22 and the circuit layer 23 to form circuit connections of desirable electrical design according to practical requirements. FIG. 2B shows a cross-sectional view of a package structure after performing the circuit built-up process on the dielectric layer 22 and the circuit layer 23 in FIG. 2A. This structure is substantially the same as the structure shown in FIG. 2A, with a difference in that a circuit built-up structure 24 is additionally formed over the dielectric layer 22 and the circuit layer 23 as shown in FIG. 2B.

Referring to FIG. 2B, the circuit built-up structure 24 comprises an insulating layer 240, a patterned circuit layer 242 formed on the insulating layer 240, and a plurality of conductive blind holes 242a penetrating the insulating layer 240 and electrically connected to the circuit layer 242, such that the plurality of conductive blind holes 242a can be electrically connected to the circuit layer 23. A plurality of electrical connection pads 244 are formed on the outermost circuit layer of the circuit built-up structure 24, and a solder mask layer 25 is applied over the outermost circuit layer and has a plurality of openings for exposing the electrical connection pads 244 where a plurality of conductive elements 260, such as solder balls, conductive pillars or bonding pillars, can be implanted. Thereby, the semiconductor chip 21 received in the substrate 20 can be electrically connected to an external electronic device through the electrode pads 210, the circuit layer 23, the circuit built-up structure 24 and the conductive elements 260.

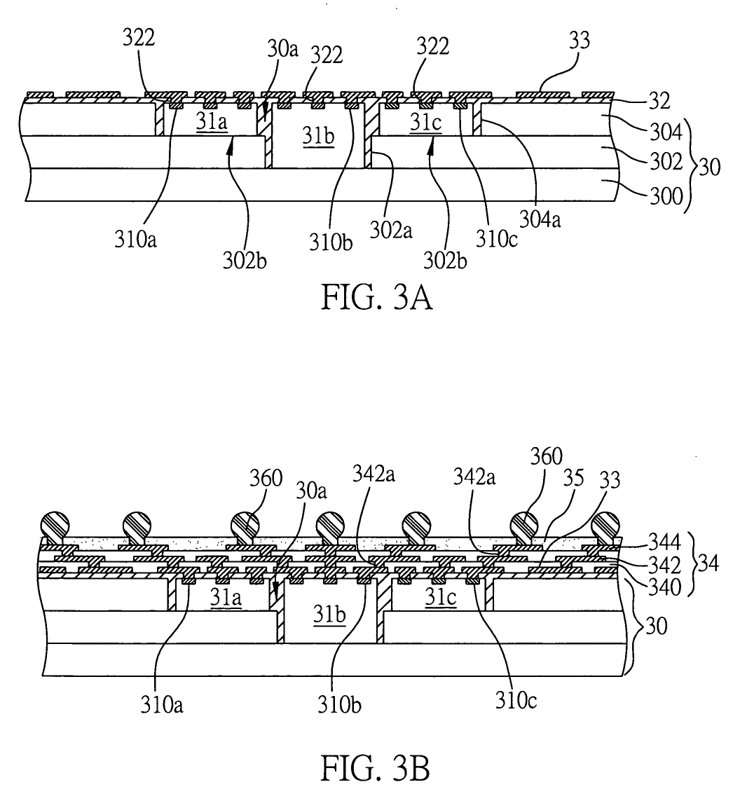

FIG. 3A shows a cross-sectional view of a package structure with chip embedded in substrate according to a second preferred embodiment of the present invention. The package structure of the second embodiment is substantially the same as the package structure of the first embodiment, but differs in that a chip set is received in the stepped cavity of the carrier. As shown in FIG. 3A, the package structure comprises a carrier 30 having at least one stepped cavity 30a; a chip set including semiconductor chips 31a, 31b, 31c and received in the stepped cavity 30a, wherein a plurality of electrode pads 310a, 310b, 310c are provided on the semiconductor chips 31a, 31b, 31c respectively; and a dielectric layer 32 formed on the semiconductor chips 31a, 31b, 31c and the carrier 30 and filled in gaps between the semiconductor chips 31a, 31b, 31c and the cavity 30a of the carrier 30 to fix the semiconductor chips 31a, 31b, 31c in the carrier 30. The package structure may further comprises a circuit layer 33 formed on the dielectric layer 32 and electrically connected to the semiconductor chips 31a, 31b, 31c.

The carrier 30 is formed by stacking a plurality of carrier layers, wherein the carrier layers except the bottommost one are each provided with at least one through opening, and the openings are increased in size layer by layer from bottom to top. An example of a three-layered carrier structure is illustrated here in this embodiment. The carrier 30 comprises a first carrier layer 300, a second carrier layer 302 and a third carrier layer 304. The second carrier layer 302 is mounted on the first carrier layer 300 and has at least one through opening 302a, wherein one side of the opening 302a is sealed by the first carrier layer 300. The third carrier layer 304 is formed with at least one through opening 304a at a position corresponding to the opening 302a of the second carrier layer 302, and the size of the opening 304a is larger than that of the opening 302a to thereby form the stepped cavity 30a with increased opening size step by step from bottom to top in the carrier 30. Thus, the stepped cavity 30a comprises the opening 302a for exposing a mounting surface 300b of the first carrier layer 300, and the opening 304a for exposing mounting surfaces 302b of the second carrier layer 302. The first, second and third carrier layers 300, 302, 304 may be an arbitrary combination of an insulating layer, a metallic layer, a ceramic layer, and a substrate formed with an internal circuit layer. It should be noted that, the above three-layered carrier structure only provides an example of the carrier 30 but not for limiting the present invention, and the number of layers of the carrier 30 may be any number according to practical requirements, for example, four layers, five layers or even more layers.

The semiconductor chips 31a, 31b, 31c are adjacently mounted on the exposed mounting surfaces 300b, 302b of the first and second carrier layers 300, 302, and are received in the stepped cavity 30a. The semiconductor chips 31a, 31b, 31c may be an arbitrary combination of active chips or passive chips, such as capacitor silicon chip, memory chip, ASIC chip, or CPU chip, etc.

The dielectric layer 32 may be made of a material, for example, epoxy resin, polyimide, cyanate ester, glass fiber, BT, or a mixture of epoxy resin and glass fiber, etc.

The circuit layer 33 can be electrically connected to the electrode pads 310a, 310b, 310c of the semiconductor chips 31a, 31b, 31c by conductive structures 322 (e.g. conductive blind holes or bumps) formed in the dielectric layer 32. The circuit layer 33 can also provide a direct electrical connection between the semiconductor chips 31a, 31b, 31c, so as to shorten an electrical connection path between the semiconductor chips, and improve transmission quality of electrical signals between the semiconductor chips, as well as reduce distortion of received signals, thereby achieving the purposes of high-speed transmission of signals and integration of electrical functions.

Subsequently for the package structure in the present invention, a circuit building-up process may be performed on the dielectric layer 32 and the circuit layer 33 to form circuit connections of desirable electrical design according to practical requirements. FIG. 3B shows a cross-sectional view of a package structure after performing the circuit built-up process on the dielectric layer 32 and the circuit layer 33 in FIG. 3A. This structure is substantially the same as the structure shown in FIG. 3A, with a difference in that a circuit built-up structure 34 is additionally formed over the dielectric layer 32 and the circuit layer 33 as shown in FIG. 3B.

Referring to FIG. 3B, the circuit built-up structure 34 comprises an insulating layer 340, a patterned circuit layer 342 formed on the insulating layer 340, and a plurality of conductive blind holes 342a penetrating the insulating layer 340 and electrically connected to the circuit layer 342, such that the plurality of conductive blind holes 342a can be electrically connected to the circuit layer 33. A plurality of electrical connection pads 344 are formed on the outermost circuit layer of the circuit built-up structure 34, and a solder mask layer 35 is applied over the outermost circuit layer and has a plurality of openings for exposing the electrical connection pads 344 where a plurality of conductive elements 360, such as solder balls, conductive pillars or bonding pillars, can be implanted. Thereby, the semiconductor chips 31a, 31b, 31c received in the carrier 30 can be electrically connected to an external electronic device through the electrode pads 310a, 310b, 310c, the circuit layer 33, the circuit built-up structure 34 and the conductive elements 360.

Therefore, in the package structure with chip embedded in substrate according to the present invention, at least one semiconductor chip (or a chip set) is received in a stepped cavity of a carrier, wherein the stepped cavity has an increased opening size step by step from bottom to top, such that a material of dielectric layer can be easily filled into the cavity to fix the semiconductor chip (or the chip set) in the cavity of the carrier, and thus surface planarity and consistency of the dielectric layer of the carrier with the semiconductor chip (or the chip set) received therein can be maintained, thereby improving the reliability of subsequent processes for forming circuits on the dielectric layer. Moreover in the present invention, a plurality of semiconductor chips with different functions (or the same function, or partially the same function) may be received in the stepped cavity of the carrier. These semiconductor chips are adjacently mounted on step surfaces of the stepped cavity, and by subsequently pressing a dielectric layer and forming a circuit layer on the semiconductor chips and the carrier, the semiconductor chips can be electrically interconnected via the circuit layer so as to shorten an electrical connection path between the semiconductor chips received in the cavity of the carrier, and improve transmission quality of electrical signals between the semiconductor chips, as well as reduce distortion of received signals, thereby achieving the purpose of high-speed transmission of signals. This therefore forms a multi-chip module structure satisfying the requirement of multi-functionality for electronic products nowadays.

Moreover, a circuit building-up process may further be performed on the dielectric layer and the circuit layer of the package structure with chip embedded in substrate according to the present invention, so as to form a multi-layered circuit structure comprising high-density fine circuits on the carrier embedded with the semiconductor chip. A plurality of conductive elements may further be implanted on an outer surface of the circuit structure to allow the semiconductor chip embedded in the carrier to be directly electrically connected to an external electronic device via the conductive elements. Therefore, the present invention can integrate the fabrication and packaging processes of semiconductor chip and carrier, thereby providing greater flexibility to satisfy clients' requirements and simplifying fabrication processes and an interface coordination problem for semiconductor manufacturers.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A package structure with chip embedded in substrate, comprising:
a carrier having at least one stepped cavity;
a semiconductor chip received in the stepped cavity, and formed with a plurality of electrode pads thereon;
a dielectric layer formed on the semiconductor chip and the carrier, and filled in a gap between the semiconductor chip and the carrier, wherein the dielectric layer is formed with conductive structures therein; and
a circuit layer formed on the dielectric layer, and electrically connected to the electrode pads of the semiconductor chip by the conductive structures in the dielectric layer.

2. The package structure with chip embedded in substrate of claim 1, further comprising at least one circuit built-up structure formed on the dielectric layer and the circuit layer, and electrically connected to the circuit layer.

3. The package structure with chip embedded in substrate of claim 2, wherein a plurality of conductive elements are implanted on an outer surface of the circuit built-up structure, for electrically connecting the semiconductor chip to an external electronic device via the conductive elements.

4. The package structure with chip embedded in substrate of claim 1, wherein the carrier comprises a first carrier layer, a second carrier layer and a third carrier layer, wherein the second carrier layer is mounted on the first carrier layer and has at least one through opening with one side of the opening of the second carrier layer being sealed by the first carrier layer, and the third carrier layer is formed with at least one through opening at a position corresponding to the opening of the second carrier layer, with the opening of the third carrier layer being larger in size than the opening of the second carrier layer, so as to form the stepped cavity with opening size increased step by step from bottom to top in the carrier.

5. The package structure with chip embedded in substrate of claim 1, wherein the carrier is an integrally formed structure, and openings with different sizes are sequentially formed in the carrier to have the stepped cavity with opening size increased step by step from bottom to top.

6. The package structure with chip embedded in substrate of claim 4, wherein the semiconductor chip is mounted on the first carrier layer and received in the stepped cavity.

7. The package structure with chip embedded in substrate of claim 4, wherein the first, second or third carrier layer is one of an insulating layer, a metallic layer, a ceramic layer, and a substrate formed with an internal circuit layer.

8. The package structure with chip embedded in substrate of claim 1, wherein the semiconductor chip is an active chip or a passive chip.

9. A package structure with chip embedded in substrate, comprising:
a carrier comprising a first carrier layer, a second carrier layer and a third carrier layer, wherein the second carrier layer is mounted on the first carrier layer and has at least one through opening, and the third carrier layer is formed with at least one through opening at a position corresponding to the opening of the second carrier layer, the opening of the third carrier layer being larger in size than the opening of the second carrier layer, so as to form a stepped cavity with opening size increased step by step from bottom to top, for exposing a mounting surface of the first carrier layer and mounting surfaces of the second carrier layer via the stepped cavity;
a plurality of semiconductor chips received in the stepped cavity of the carrier and mounted on the mounting surfaces of the first and second carrier layers, wherein the semiconductor chips are formed with a plurality of electrode pads thereon;
a dielectric layer formed on the semiconductor chips and the carrier, and filled in gaps between the semiconductor chips and the carrier, wherein the dielectric layer is formed with conductive structures therein; and
a circuit layer formed on the dielectric layer, and electrically connected to the electrode pads of the semiconductor chips by the conductive structures in the dielectric layer.

10. The package structure with chip embedded in substrate of claim 9, further comprising at least one circuit built-up structure formed on the dielectric layer and the circuit layer, and electrically connected to the circuit layer.

11. The package structure with chip embedded in substrate of claim 10, wherein a plurality of conductive elements are implanted on an outer surface of the circuit built-up structure, for electrically connecting the semiconductor chips to an external electronic device via the conductive elements.

12. The package structure with chip embedded in substrate of claim 9, wherein each of the semiconductor chips is an active chip or a passive chip.
